(19) United States
(12) Patent Application Publication
(10) Pub. No.: US 2025/0151322 A1
(43) Pub. Date: May 8, 2025

(54) MOSFET DEVICE WITH SHIELDING REGION AND MANUFACTURING METHOD THEREOF

(71) Applicant: STMicroelectronics S.r.l., Agrate Brianza (IT)

(72) Inventors: Mario Giuseppe SAGGIO, Aci Bonaccorsi (IT); Edoardo ZANETTI, Valverde (IT)

(73) Assignee: STMicroelectronics S.r.l., Agrate Brianza (IT)

(21) Appl. No.: 18/915,694

(22) Filed: Oct. 15, 2024

Related U.S. Application Data
(63) Continuation of application No. 17/665,398, filed on Feb. 4, 2022, now Pat. No. 12,148,824.
Application No. 17/665,398 is a division of application No. 16/528,410, filed on Jul. 31, 2019, now Pat. No. 11,251,296.

(30) Foreign Application Priority Data
Aug. 2, 2018 (IT) 102018000007780

(51) Int. Cl. H10D 30/66; H01L 21/70; H10D 30/01; H10D 62/10; H10D 62/17; H10D 62/832; H10D 64/27

(52) U.S. Cl. CPC H10D 30/668; H01L 21/70; H10D 30/0297; H10D 62/109; H10D 62/393; H10D 62/8325; H10D 64/513; H10D 62/106

(57) ABSTRACT

A MOSFET device comprising: a structural region, made of a semiconductor material having a first type of conductivity, which extends between a first side and a second side opposite to the first side along an axis; a body region, having a second type of conductivity opposite to the first type, which extends in the structural region starting from the first side; a source region, having the first type of conductivity, which extends in the body region starting from the first side; a gate region, which extends in the structural region starting from the first side, traversing entirely the body region; and a shielding region, having the second type of conductivity, which extends in the structural region between the gate region and the second side. The shielding region is an implanted region self-aligned, in top view, to the gate region.

### BACKGROUND

### Technical Field

The present disclosure relates to a silicon carbide MOSFET device and to a manufacturing method thereof. In particular, the present disclosure relates to a MOSFET device with low on-state resistance and high reliability.

### Description of the Related Art

Known to the art are MOSFETs (Metal-Oxide-Semiconductor Field-Effect Transistors) made of silicon carbide (SiC) for power-electronics applications. In particular, the silicon carbide MOSFETs present advantages over power MOSFETs of a conventional type, thanks to their characteristics of reduction of the energy losses and to their small dimensions.

An aim in the design of a silicon carbide MOSFET regards protection of the gate-dielectric regions in reverse-biasing conditions during use of the transistor, i.e., when the aforesaid regions are subject to high electrical fields. A better protection of the gate-dielectric regions enables proper operation of said transistors also at higher operating voltages, without jeopardizing reliability thereof.

In particular, silicon carbide MOSFETs may be made in such a way that they have a planar structure or a trench-gate structure. Planar-structure transistors typically have a lower channel mobility than trench-gate transistors.

An example of trench silicon carbide MOSFET of a known type (referred to hereinafter for simplicity as “device 1”) is provided in FIG. 1, where it is represented in lateral sectional view in a system of spatial co-ordinates defined by mutually orthogonal axes X, Y, and Z.

The device 1 comprises a semiconductor body 2 made of silicon carbide.

In particular, the semiconductor body 2 comprises a substrate 4 and a structural region 6. The substrate 4 is made of silicon carbide having a conductivity of a first type (here, an N type) and a first doping concentration. The substrate 4 is delimited by a first side 4a and a second side 4b opposite to one another in the direction Z.

The structural region 6 is likewise made of silicon carbide, having a conductivity of the first type (N) and a second doping concentration lower than the first doping concentration. The structural region 6 extends over the substrate 4 and is delimited by a first side 6a and a second side 6b, which is opposite to the first side 6a in the direction Z and is in contact with the substrate 4 on its first side.

A body region 8, having a conductivity of a second type (here a P type), different from the first type, extends within the structural region 6, with main direction of extension substantially parallel to the plane XY.

A source region 10, having a conductivity of the first type (N), extends on the body region 8, with main direction of extension parallel to the plane XY. In particular, a first side of the source region 10 is in contact with the body region 8, whereas a second side of the source region 10, opposite to the first side in the direction Z, coincides with the first side 6a of the structural region 6.

A first gate region 12a extends in depth within the structural region 6, starting from its first side 6a. In particular, the first gate region 12a traverses entirely the source region 10 and the body region 8, and extends in depth beyond the body region 8.

A second gate region 12b, equivalent from a structural and functional standpoint to the first gate region 12a, extends in depth within the structural region 6, starting from its first side 6a, at a distance from the first gate region 12a. As has been said for the first gate region 12a, the second gate region 12b traverses entirely the source region 10 and the body region 8 and extends in depth beyond the body region 8.

The first and second gate regions 12a, 12b, comprise, respectively, a first gate electrode 12a′ and a second gate electrode 12b′, made of conductive material. Moreover, the first and second gate regions 12a, 12b comprise, respectively, a first gate dielectric 12a″ and a second gate dielectric 12b″, made of insulating material.

In particular, the first and second gate dielectrics 12a″, 12b″ coat the first and second gate electrodes 12a′, 12b′ in such a way that the first and second gate electrodes 12a′, 12b′ are not in direct contact with the source region 10, the body region 8, and the structural region 6.

During use of the device 1, in a known way, conductive channels are formed at the interface between the body region 8 and, respectively, the first and second gate dielectrics 12a″, 12b″.

A shielding region 14, having a conductivity of the second type (P), extends within the structural region 6, at a distance from the first and second gate regions 12a, 12b, on a respective side of the latter. More in particular, the shielding region 14 does not extend between the first and second gate regions 12a, 12b. The shielding region 14 extends in depth starting from the first side 6a of the structural region 6, reaching a depth greater than that of the body region 8.

The device 1 further comprises an intermediate dielectric region 18, which extends, at the first side 6a of the structural region 6, over the source region 10, the first and second gate regions 12a, 12b, and the shielding region 14. In particular, the intermediate dielectric region 18 covers the first and second gate regions 12a, 12b entirely.

The device 1 further comprises a source electrode 20, which extends over the intermediate dielectric region 18 and within openings in the intermediate dielectric region 18, at regions of the first side 6a of the structural region 6 not covered by the intermediate dielectric region 18.

The device 1 further comprises a drain electrode 22, which extends underneath the semiconductor body 2.

A contact region 16, having a conductivity of the first type (N+) and a third doping concentration higher than the second doping concentration, extends between, and at a distance from, the first and second gate regions 12a, 12b, in depth in the structural region 6 starting from the first side 6a. In particular, the depth, along Z, at which the contact region 16 extends corresponds to the depth at which the source region 10 extends.

A central implantation region 24, having a conductivity of the second type (P), extends between the first and second gate regions 12a, 12b, and at a distance from the latter, within the structural region 6 and immediately underneath the contact region 16 and the source region 10. In particular, the central implantation region 24 extends in depth in the structural region 6, beyond the depth, measured along the axis Z, reached by the body region 10.

In particular, the central implantation region 24 extends at a first distance TTPL from the first gate region 12a, and at a second distance TTPR from the second gate region 12b, the first and second distances TTPL, TTPR being the minimum distances between the central implantation region 24 and the first and second gate regions 12a, 12b measured in the direction X.

Likewise, also the shielding regions 14 extend at respective minimum distances TTPL′ and TTPR′ from the respective first and second gate regions 12a, 12b that they face directly.

As is known, the shielding region 14 and the central implantation region 24 are designed so as to reduce, given the same reverse-biasing voltage applied, the electrical field at the first and second gate dielectrics 12a″, 12b″. In effect, an aim in design of the device 1 consists in guaranteeing that the first and second gate dielectrics 12a″, 12b″ will be able to withstand the electrical fields in any operating condition.

For this purpose, there is known the possibility of increasing the thickness of the first and second gate dielectrics 12a″, 12b″. However, this design solution entails an undesirable increase in the extension in the plane XY of the area of the first and second gate regions 12a, 12b, thus limiting the efficiency of the device 1 and increasing the area occupied thereby.

It is moreover known that the efficiency of the central implantation region 24 in limiting the electrical field at the first and second gate dielectrics 12a″, 12b″ depends, respectively, upon the values of the first and second distances TTPL, TTPR, as well as upon the values of the distances TTPL′ and TTPR′. In particular, it is known that the distances TTPL, TTPR, TTPL′, and TTPR′ should preferably be comprised in a range around an ideal value. However, a possible drawback of this solution applied to the device 1 is caused by the methods typically used for manufacturing the device 1. In particular, it is common to produce the first and second gate regions 12a, 12b using a first photolithographic mask, whereas the central implantation region 24 and the shielding regions 14 are obtained using one and the same second photolithographic mask, or successive second photolithographic masks. Consequently, any inevitable imprecision of alignment between the first and the one or more second photolithographic masks mean that the distances TTPL, TTPR, TTPL′, and TTPR′ are, in effect, all different from one another, thus unbalancing the electrical behavior of the device 1. In particular, the resulting asymmetry means that one of the first and second gate dielectrics 12a″, 12b″ is subjected to a stronger electrical field given the same operating voltage, hence causing a lower breakdown voltage for the device 1. Added to this is a degradation of the gate oxide, which jeopardizes the reliability during the service life of the device 1.

### BRIEF SUMMARY

One or more embodiments of the present disclosure provide a silicon carbide MOSFET device with low on-state resistance and high reliability, and a manufacturing method thereof, alternative to those of a known type. Such one or more embodiments provide a MOSFET device and a method for manufacturing the MOSFET device that will be able to overcome or reduce the drawbacks of the prior art mentioned previously.

According to the present disclosure a MOSFET device and a method for manufacturing the MOSFET device are provided.

### BRIEF DESCRIPTION OF THE SEVERAL VIEWS OF THE DRAWINGS

For an understanding of the present disclosure, preferred embodiments thereof are now described, purely by way of non-limiting example, with reference to the attached drawings, wherein:

FIG. 1 is a schematic lateral sectional view of a MOSFET device of a known type;

FIG. 2 is a schematic lateral sectional view of a MOSFET device according to an embodiment of the present disclosure;

FIGS. 3A-3F are schematic lateral sectional views of respective manufacturing steps of a MOSFET device according to an embodiment of the present disclosure; and

FIG. 4 illustrates an elementary cell of the MOSFET device of FIG. 2.

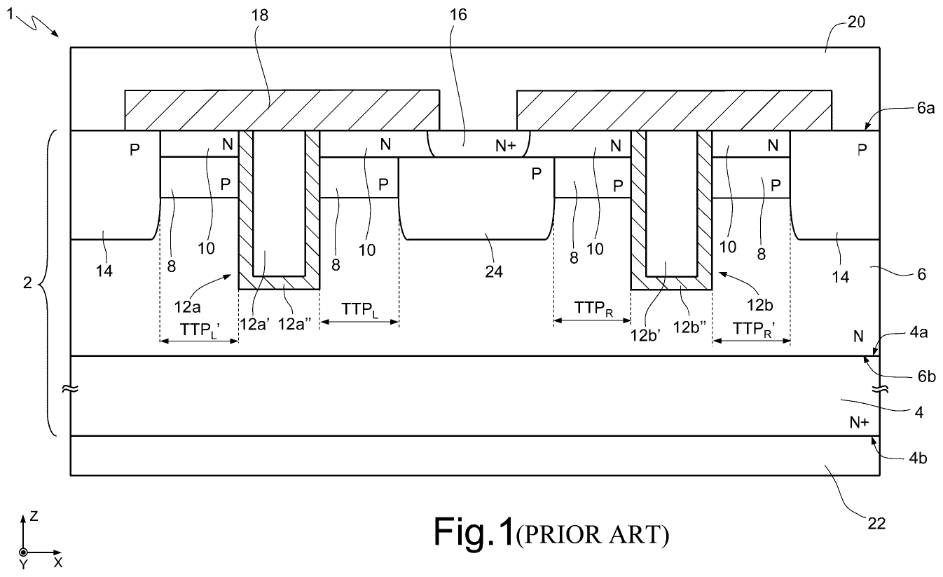

### DETAILED DESCRIPTION

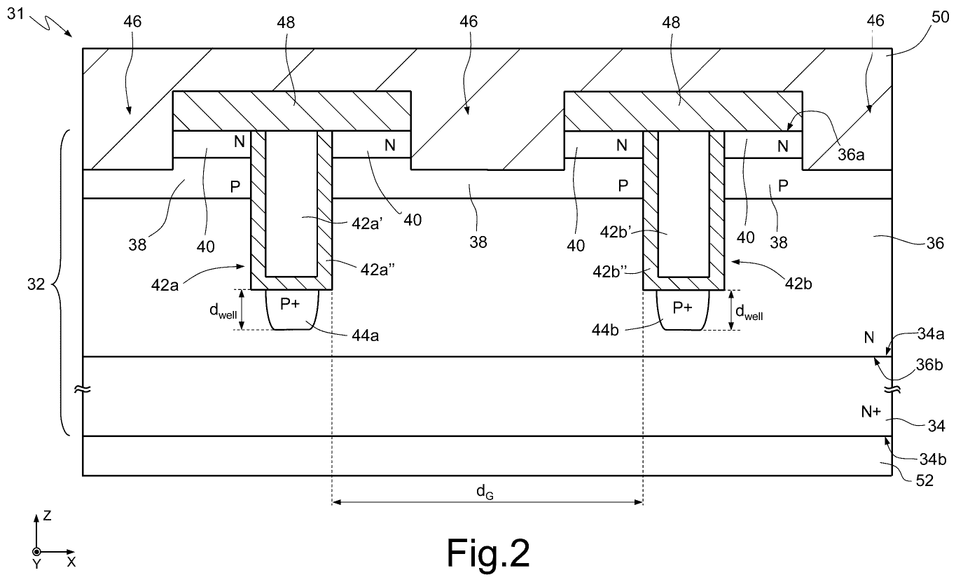

FIG. 2 is a schematic illustration of a trench-gate MOSFET 31 according to an embodiment of the present disclosure. For simplicity, in the rest of the description, it will be referred to as “MOSFET device 31”. The MOSFET device 31 is illustrated in lateral sectional view in a system of spatial co-ordinates defined by mutually orthogonal axes X, Y, and Z.

The MOSFET device 31 comprises a semiconductor body 32 made of silicon carbide. The semiconductor body 32 comprises a substrate 34 and a structural body 36.

The substrate 34 is made of a semiconductor material, for example silicon carbide SiC, having a conductivity of a first type (here, an N type) and a first doping concentration, for example, higher than 10¹⁸ atoms/cm³. The substrate 34 is delimited by a first side 34a and a second side 34b opposite to one another in the direction Z.

The structural body 36 likewise may be made of silicon carbide, extends over the substrate 34, and is delimited by a first side 36a and by a second side 36b, which is opposite to the first side 36a in the direction Z. In particular, the second side 36b of the structural body 36 coincides with the first side 34a of the substrate 34. The structural body 36 has a thickness, measured in the direction Z, comprised, for example between 1 μm and 100 μm, for example 10 μm, for withstanding, in use, voltages of between 100 V and 20 kV.

A body region 38, having a conductivity of a second type (here a P type), different from the first type, extends within the structural body 36 starting from its first side 36a and in depth along Z. In particular, the body region 38 has a doping concentration comprised, for example, between 10¹⁵ atoms/cm³ and 10¹⁸ atoms/cm³, for example 10¹⁷ atoms/cm³, for withstanding, in use, voltages of between 100 V and 20 kV.

A source region 40, having a conductivity of the first type (N), extends within the body region 38 starting from the first side 36a of the structural body 36. In particular, the source region 40 has a doping concentration comprised, for example, between 10¹⁸ atoms/cm³ and 10²¹ atoms/cm³, for example 10²⁰ atoms/cm³.

In particular, the source region 40 extends within the structural body 36 down to a maximum depth comprised, for example, between 0.1 μm and 0.5 μm, for example 0.3 μm, where said depth is considered in the direction Z starting from the first side 36a of the structural body 36. The body region 38 extends within the structural body 36 down to a depth comprised, for example, between 0.3 μm and 1 μm, for example 0.6 μm, considered in the direction Z starting from the first side 36a of the structural body 36.

The portions of the structural body 36 not occupied by the body region 38 and the source region 40 have a conductivity of the first type (N) and a second doping concentration lower than the first doping concentration, for example of between 10¹⁴ atoms/cm³ and 10¹⁷ atoms/cm³, for example 10¹⁶ atoms/cm³. In practice, the concentration of dopant species of the structural body 36 may be chosen in such a way as to bestow on the latter a resistivity of between 6.25 Ω·cm and 0.125 Ω·cm.

A first gate region 42a extends in depth within the structural body 36, starting from its first side 36a. In particular, the first gate region 42a traverses entirely the source region 40 and the body region 38, and extends beyond the body region 38 down to a depth comprised, for example, between 0.4 μm and 10 μm, for example 1.5 μm, terminating within the structural body 36.

A second gate region 42b, structurally and functionally similar to the first gate region 42a, extends in depth within the structural body 36, starting from its first side 36a in a main direction substantially parallel to the axis Z. The first and second gate regions 42a, 42b are at a distance from one another. As has been said for the first gate region 42a, the second gate region 42b traverses entirely the source region 40 and the body region 38, and extends beyond the body region 38 reaching the same depth as the first gate region 42a, and terminating within the structural body 36.

In particular, the first and second gate regions 42a, 42b are at a distance de from one another comprised, for example, between 1 μm and 5 μm, for example 2 μm. This distance de is the minimum distance, measured in the direction X, between the first and second gate regions 42a, 42b.

The first and second gate regions 42a, 42b comprise, respectively, a first gate electrode 42a′ and a second gate electrode 42b′, made of conductive material such as doped polysilicon, and a respective first gate dielectric 42a″ and second gate dielectric 42b″, made of insulating material such as silicon dioxide (SiO₂).

In particular, the first and second gate dielectrics 42a″, 42b″ surround or coat, respectively, the first and second gate electrodes 42a′, 42b′ in such a way that the first and second gate electrodes 42a′, 42b′ are not in direct contact with the source region 40, the body region 38, and the structural body 36. In other words, the first and second gate dielectrics 42a″, 42b″ electrically insulate the first and second gate electrodes 42a′, 42b′ from the source region 40, from the body region 38, and from the structural body 36.

By way of example, the first and second gate dielectrics 42a″, 42b″ have a thickness comprised, for example, between 10 nm and 150 nm, for example, 50 nm.

In a way in itself known, during use of the device 31 conductive channels are formed at the interface between the body region 38 and, respectively, the first and second gate dielectrics 42a″, 42b″.

According to one aspect of the present disclosure, a first shielding region 44a and a second shielding region 44b, having a conductivity of the second type (P+), extend underneath the first and second gate regions 42a, 42b, respectively, in contact with the first and second gate dielectrics 42a″, 42b″, respectively, at the bottom of the respective gate region 42a, 42b.

In particular, the first and second shielding regions 44a, 44b extend within the structural body 36, without reaching the substrate 34. In particular, the first and second shielding regions 44a, 44b extend down to a depth dwell comprised, for example, between 0.1 μm and 0.3 μm, for example 0.2 μm, where said depth is measured in the direction Z starting from the interface with the bottom of the respective gate region 42a, 42b.

The first and second shielding regions 44a, 44b have a doping concentration comprised between 10¹⁷ atoms/cm³ and 10²¹ atoms/cm³, for example 10²⁰ atoms/cm³. According to one aspect of the present disclosure, the concentration of dopant species of the first and second shielding regions 44a, 44b is chosen so as to bestow thereon a resistivity of between 2.5.10-1 Ω·cm and 6.5.10-3 Ω·cm.

According to one aspect of the present disclosure, the first and second shielding regions 44a, 44b are aligned, in the direction Z, with the first and second gate regions 42a, 42b, respectively. In particular, in a top plan view in the plane XY (not illustrated in the figures), the first shielding region 44a extends over an area equal to or greater than the area of extension of the first gate electrode 42a′, but smaller than the area of extension of the first gate dielectric 42a″. This may also apply to the alignment between the second gate region 42b and the second shielding region 44b. In other words, the first and second shielding regions 44b extend exclusively underneath the first and second gate regions 42a, 42b, respectively.

According to one aspect of the present disclosure, the presence of the first and second shielding regions 44a, 44b enables reduction of the electrical field, during use of the MOSFET device 31, in the proximity of the first and second gate dielectrics 42a″, 42b″, thus improving the reliability of the MOSFET device 31.

Moreover, thanks to the alignment between the first and second gate regions 42a, 42b and the respective first and second shielding regions 44a, 44b, and in particular thanks to the fact that the first and second shielding regions 44a, 44b do not project outside the respective first and second gate regions 42a, 42b, the first and second shielding regions 44a, 44b do not interfere with the conductive channels, and consequently the on-state resistance of the MOSFET device 31 is not inconveniently increased.

The MOSFET device 31 further comprises an intermediate dielectric region 48, which extends, at the first side 36a of the structural body 36, over the source region 40 and over the first and second gate regions 42a, 42b. In particular, the intermediate dielectric region 48 covers entirely the first and second gate regions 42a, 42b. In particular, the intermediate dielectric region 48 is made of insulating material, such as TEOS, and has a thickness comprised, for example, between 0.2 μm and 2 μm, for example 0.5 μm.

Contact regions (trenches) 46 extend alongside each intermediate dielectric region 48, completely through the source region 40 and partially through the body region 38, terminating within the latter. In one embodiment, the trenches 46 have an extension, in top view in the plane XY, that is continuous along the axis Y.

In a different embodiment (not illustrated), each trench 46 has an extension, in top view in the plane XY, of a discontinuous type, including trench sub-portions aligned along the axis Y and alternating with full regions. This embodiment presents the advantage of maximizing the area of contact with the source region 40. In a further embodiment (not illustrated either), the MOSFET device 31 does not have trenches 46. In this case, the electrical contact with the body region 38 occurs by means of implanted regions, having the second type of conductivity (P), which extend through the source regions 40 until they reach and contact the underlying body regions 38. The shape and extension of said implanted regions substantially replicates the shape and extension described for the trenches 46 in the context of the present disclosure (for example, they have an extension, in top view in the plane XY, of a discontinuous type, including implanted sub-portions aligned along the axis Y alternating with regions in which the implant is absent).

The MOSFET device 31 further comprises a source electrode 50, made of conductive material, which extends over the intermediate dielectric region 48 and within the contact regions 46. The source electrode 50 is hence in electrical contact with the source regions 40 and with the body regions 38. Each contact region 46 extends at a distance from the first and second gate regions 42a, 42b in such a way that the source electrode 50 is in direct electrical contact with the source region 40 and the body region 38, but is not in direct electrical contact with the first and second gate regions 42a, 42b. In particular, the contact region 46 extends in a central position between the first and second gate regions 42a, 42b, and outside the area between the first and second gate regions 42a, 42b. In other words, the contact region 46 extends outside each gate region 42a, 42b, giving out on opposite sides in the direction X of each gate region 42a, 42b.

In particular, the extension of the first and second gate regions 42a, 42b and of the source electrode 50 through the source region 40 means that the source region 40 comprises a plurality of subregions, amongst which: a first source subregion between the source electrode 50 and a first side of the first gate dielectric 42a″; a second source subregion between the source electrode 50 and a second side of the first gate dielectric 42a″, opposite to the first side in the direction X; a third source subregion between the source electrode 50 and a first side of the second gate dielectric 42b″; a fourth source subregion between the source electrode 50 and a second side of the second gate dielectric 42b″, opposite to the first side in the direction X. In other words, each gate region 42a, 42b is interposed between two source subregions.

The MOSFET device 31 further comprises a drain electrode 52, made of conductive material, which extends on the back of the semiconductor body 32, i.e., on the second side 34b of the substrate 34.

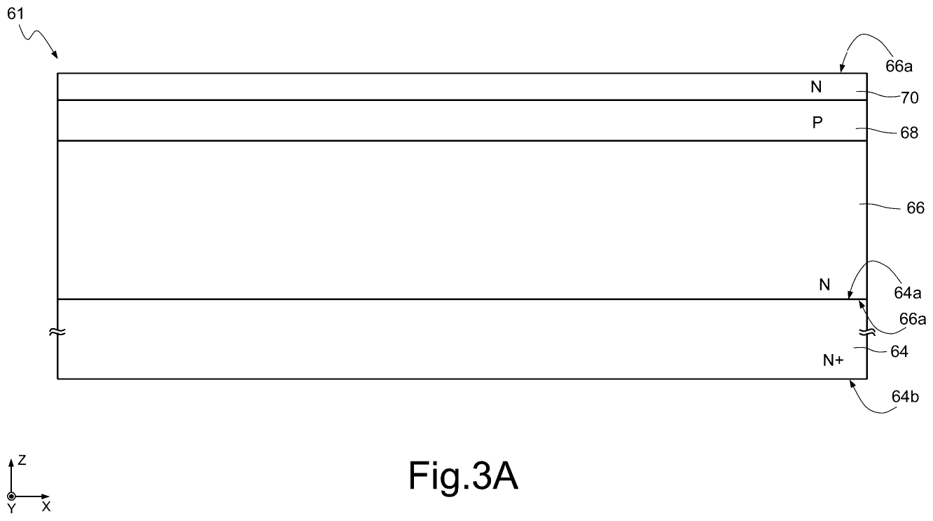

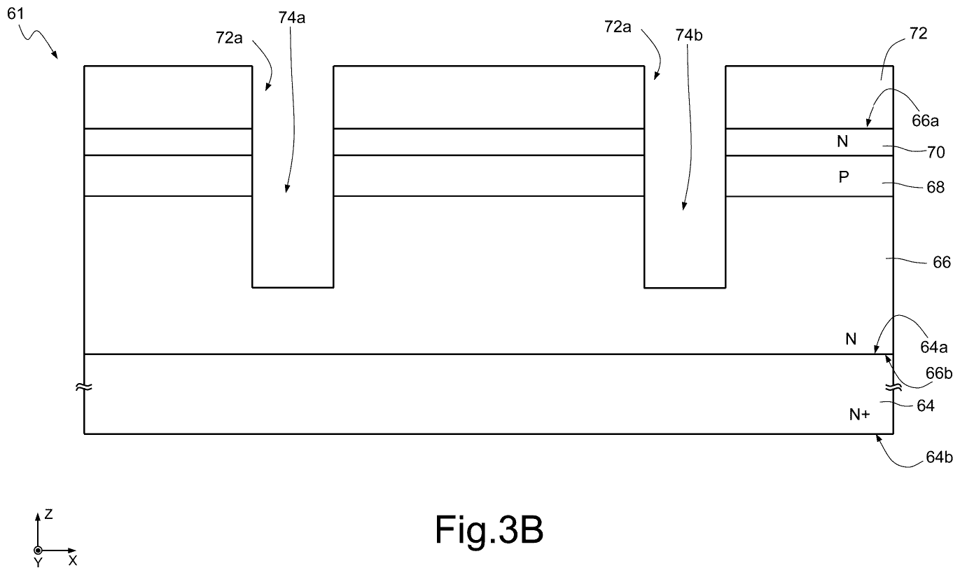

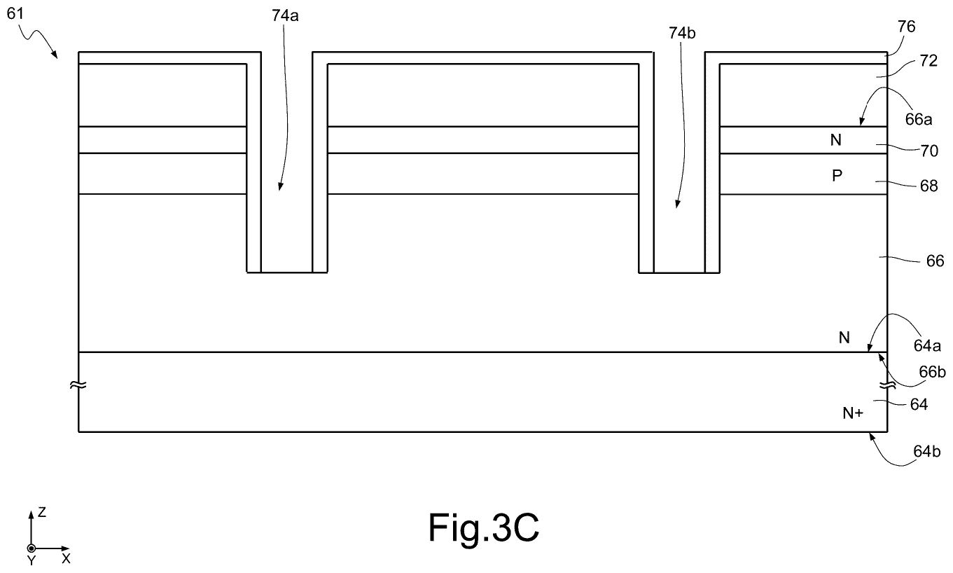

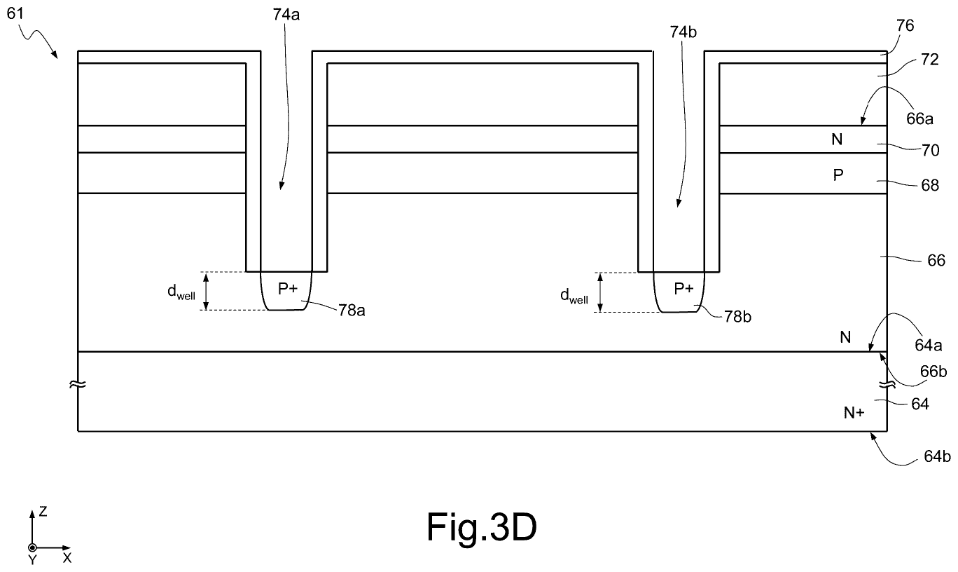

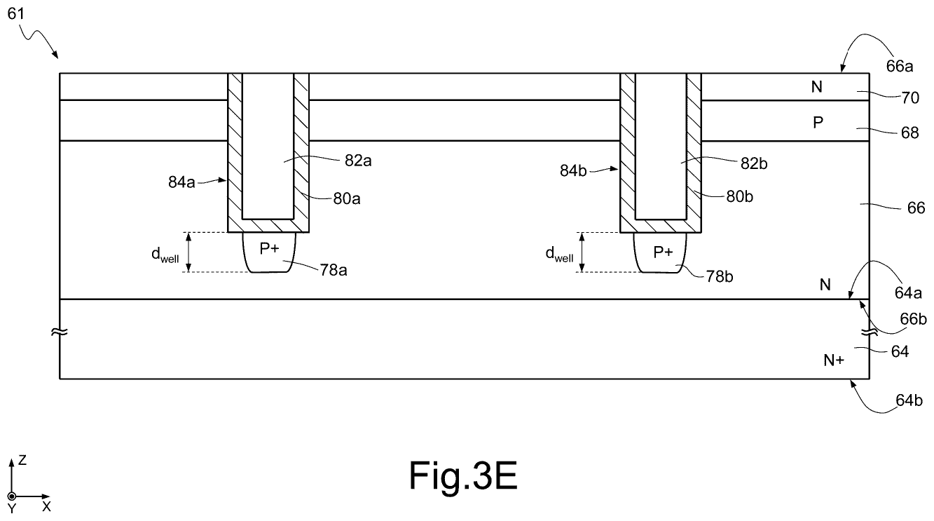

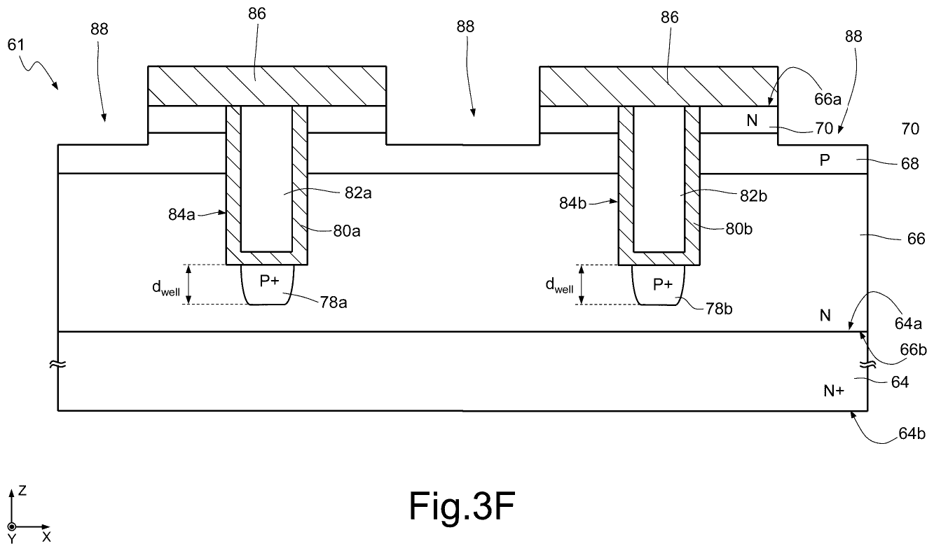

The steps for manufacturing the MOSFET device according to the present disclosure are described in what follows with reference to FIGS. 3A-3F. FIGS. 3A-3F illustrate, in lateral sectional view in the plane XZ, the MOSFET device in the system of spatial co-ordinates X, Y, and Z of FIG. 2.

FIG. 3A illustrates a portion of a wafer 61 comprising a substrate 64, in particular made of silicon carbide having a conductivity of a first type (here, an N type) and a first doping concentration, for example higher than 10¹⁸ atoms/cm³. The substrate 64 is delimited by a first side 64a and by a second side 64b opposite to one another in the direction Z.

On top of the substrate 64 a structural layer 66 is formed, for example, by of epitaxial growth of silicon carbide on the first side 64a of the substrate 64. The epitaxial growth is carried out according to known techniques and in such a way that the structural layer 66 has the first type of conductivity (N) and a second doping concentration lower than the first doping concentration, comprised, for example, between 10¹⁴ atoms/cm³ and 10¹⁷ atoms/cm³, for example 10¹⁶ atoms/cm³. Moreover, the epitaxial growth is carried out until a thickness of the structural layer 66 comprised, for example, between 1 μm and 100 μm, for example 10 μm is reached. The structural layer 66 is delimited by a first side 66a and a second side 66b, opposite to one another in the direction Z; in particular, the second side 66b coincides with the first side 64a of the substrate 64.

Then, using implantation techniques in a way in itself known, a body layer is formed 68 having a conductivity of a second type (here a P type), in particular by means of implantation of dopant ion species of a P type, for example aluminum, on the first side 66a of the structural layer 66. In particular, the implantation dose is, by way of example, of between 10¹² and 10¹³ atoms/cm³ and the implantation energies are comprised, by way of example, between 150 keV and 700 keV, so as to reach a depth, measured in the direction Z starting from the first side 66a of the structural layer 66, of between, for example, 0.1 μm and 1 μm, for example 0.6 μm.

Then, using implantation techniques of a type in itself known, a source layer is formed 70 having a conductivity of the first type (here, an N type), in particular by means of implantation of dopant ion species of an N type, such as nitrogen or phosphorous, on the first side 66a of the structural layer 66. In particular, the implantation dose is by way of example of between 10¹³ and 10¹⁵ atoms/cm³ and the implantation energies are comprised, by way of example, between 50 keV and 300 keV, so as to reach a depth less than the depth reached by the body layer 68 and comprised, for example, between 0.1 μm and 0.5 μm, for example 0.3 μm.

As an alternative to what has been described, the body layer 68 and the source layer 70 may be formed by means of subsequent epitaxial growths of material (here, SiC) appropriately doped.

This is followed (FIG. 3B) by a step of selective etching of the structural layer 66 by means of photolithographic and etching techniques of a type in itself known, using a mask 72 formed on the first side 66a of the structural layer 66. In particular, the mask 72 is made of insulating material such as TEOS or silicon nitride (Si₃N₄), and has openings 72a in the areas in which the first and second gate regions 42a, 42b of the MOSFET device 31 of FIG. 2 are to be formed, in subsequent processing steps.

The step of etching through the mask 72, illustrated in FIG. 3B, forms a plurality of trenches in the structural layer 66 at the openings 72a of the mask 72. In particular, the etching step forms a first trench 74a and a second trench 74b. In particular, the etching step proceeds for a time necessary for the first and second trenches 74a, 74b to pass completely through the source layer 70 and the body layer 68. In particular, the depth, along Z, of the first and second trenches 74a, 74b is comprised, for example, between 0.4 μm and 10 μm, for example 1.5 μm. The trenches 74a, 74b have a width, measured along the axis X, comprised, for example, between 0.5 μm and 1 μm, for example 0.6 μm. The extension along the axis Y of the trenches 74a, 74b is equal to the extension of the active area.

This is followed (FIG. 3C) by formation of a spacer layer 76 made of insulating material, such as TEOS or Si₃N₄, on top of the mask 72 and within the first and second trenches 74a, 74b, filling them partially. In particular, the spacer layer 76 is formed by growth or deposition in a conformable way within the first and second trenches 74a, 74b and extends both on the bottom of the trenches and on the side walls. Even more in particular, subsequent to the step of formation of the spacer layer 76, the structural layer 66 is completely covered.

This is followed by a step of etching of the spacer layer 76, in a selective way with respect to the structural layer 66, in order to expose the structural layer 66 at the bottom of the first and second trenches 74a, 74b. According to one aspect of the present disclosure, said etching step is carried out in such a way that, at the end thereof, the spacer layer 76 continues to cover the side walls of the first and second trenches 74a, 74b completely, but not the bottom of the first and second trenches 74a, 74b. In particular, the steps of formation and non-masked etching of the spacer layer 76 are designed according to known techniques in such a way that at the end of the etching step, the thickness of the spacer layer 76 at the side walls of the first and second trenches 74a, 74b is comprised, for example, between 50 nm and 300 nm, for example 100 nm, where said thickness is measured in the direction X. By way of example, said etching step is of an anisotropic dry type (e.g., RIE), preferably acting in the direction Z, in such a way that the rate of removal of the spacer layer 76 at the bottom of the trenches 74a, 74b is higher than the rate of removal of the spacer layer 76 at the side walls of the trenches 74a, 74b.

This is followed (FIG. 3D) by a step of formation of the shielding regions 44a, 44b of FIG. 2. For this purpose, an ion implantation of dopant impurities, for example aluminum, is carried out in order to form a first implanted region 78a and a second implanted region 78a78b having a conductivity of the second type (P+) on the bottom of the first and second trenches 74a, 74b, respectively. In particular, during the implantation step, the mask 72 and the spacer layer 76 function as implantation mask, preventing penetration of dopant impurities within the structural layer 66 except for the region at the bottom of the first and second trenches 74a, 74b.

In particular, the implantation dose is, by way of example, of between 10¹³ and 10¹⁵ atoms/cm³ and the implantation energies are comprised, by way of example, between 10 keV and 80 ke V.

A subsequent step of thermal diffusion completes formation of the shielding regions 44a, 44b.

In particular, the implantation step is designed in such a way that the first and second shielding regions 78a, 78b extend for a depth dwell of between 100 nm and 300 nm, for example 200 nm, where the depth is measured in the direction Z starting from the bottom of the first and second trenches 74a, 74b.

According to one aspect of the present disclosure, the presence of the spacer layer 76 on the side walls of the first and second trenches 74a, 74b means that, at the end of the implantation step, the first and second shielding regions 78a, 78b do not extend, in top plan view in the plane XY, outside the area in which the first and second trenches 74a, 74b had previously been formed.

The first and second shielding regions 44a, 44b of the MOSFET device 31 of FIG. 2 are thus formed.

This is followed (FIG. 3E) by a step of wet etching of the mask 72 and of the spacer layer 76, selectively with respect to the structural layer 66, in order to remove completely the mask 72 and the spacer layer 76 both on top of the structural layer 66 and within the first and second trenches 74a, 74b.

Next, the first and second trenches 74a, 74b are filled with a gate-dielectric layer and a gate-metallization layer, in a way in itself evident to the person skilled in the art.

In particular, the gate-dielectric layer, made of insulating material, such as SiO₂, Al₂O₃, HfO₂, is deposited on the structural layer 66, on its first side 66, and inside the first and second trenches 74a, 74b.

In particular, the gate-dielectric layer is formed by growth or deposition in a conformable way within the first and second trenches 74a, 74b and extends both on the bottom of the trenches and on the side walls. In other words, subsequent to the step of formation of the gate-dielectric layer, the structural layer 66 is completely covered.

In particular, the gate-dielectric layer has a thickness comprised, for example, between 10 nm and 200 nm, for example 50 nm, so as to fill the first and second trenches 74a, 74b only partially.

Then, the gate-metallization layer is deposited so as to fill the first and second trenches 74a, 74b and is subsequently patterned by means of an etching step to form respective gate electrodes 82a, 82b. The first and second gate electrodes 42a′, 42b′ are thus formed, and consequently the first and second gate regions 42a, 42b of the MOSFET device 31 of FIG. 2, designated, respectively, by the reference numbers 84a, 84b in FIG. 3E.

Next (FIG. 3F), an intermediate dielectric layer 86 is formed on the first side 66a of the structural layer 66, on top of the source layer 70. In particular, the intermediate dielectric layer 86 covers the first and second gate regions 84a, 84b entirely. In particular, the intermediate dielectric layer 86 is made of insulating material, such as TEOS, and has a thickness comprised, for example, between 0.2 μm and 2 μm, for example 0.5 μm.

Then, an etching step is carried out aimed at forming a plurality of trenches 88 in the structural layer 66 on its first side 66a. In particular, the trenches 88 extend on opposite sides in the direction X of each between the first and second gate regions 84a, 84b. In particular, the etching step starts with an etch of the intermediate dielectric layer 86, and then extends throughout the thickness of the source layer 70 and partially into the body layer 68. In other words, the trenches 88 extend at a distance from the first and second gate regions 84a, 84b, in regions where it is intended to form the contact regions 46 of the MOSFET device 31 of FIG. 2. The intermediate dielectric region 48 and the source subregions of the source region 40 of the MOSFET device 31 of FIG. 2 are thus formed.

Next, in a way not illustrated in FIG. 3F, a source metallization is formed by depositing conductive material on the wafer 61 in such a way that it fills the trenches 88 completely and extends over the intermediate dielectric layer 86.

Finally, in a way not illustrated in FIG. 3F, a drain metallization is formed by depositing conductive material on the opposite side of the wafer 61, in contact with the substrate 64.

In this way, the MOSFET device 31 of FIG. 2 is formed.

From an examination of the characteristics of the present disclosure, the advantages that it affords are evident.

In particular, the presence of the shielding regions at the bottom of the trench-gate regions means that the gate dielectrics are subject to electrical fields of lower intensity. Consequently, the MOSFET device can operate at higher voltages without being damaged. The reliability of the MOSFET device is thus improved.

Moreover, the fact that the manufacturing method is based upon a self-alignment of each gate region to the respective shielding region means that no shielding region projects alongside the respective gate region, interfering with the respective conductive channel. Consequently, the properties of conduction of the MOSFET device are not adversely affected by the presence of the shielding regions. In particular, the on-state resistance is not increased.

In addition, the fact that the manufacturing method is based upon a self-alignment of each gate region to the respective shielding region means that it is possible to reduce the distance between the gate regions, thus favoring miniaturization of the MOSFET device.

The problems of unbalancing of the electrical behavior of the device, identified with reference to the prior art, are moreover overcome.

Finally, it is clear that modifications and variations may be made to the device and method described and illustrated herein, without thereby departing from the sphere of protection of the present disclosure.

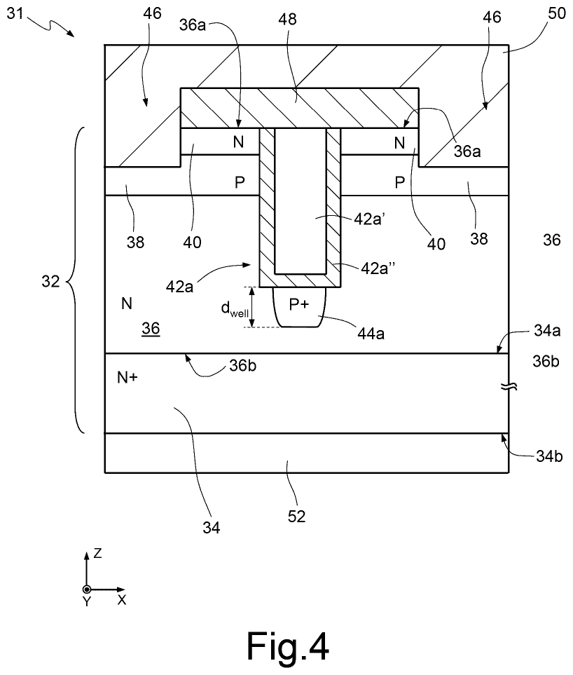

In particular, it is evident that the MOSFET device 31 of FIG. 2 may comprise any number (chosen according to the need) of gate regions by replicating an elementary cell constituted by the gate region and by the respective self-aligned shielding region. FIG. 4 illustrates an elementary cell of the MOSFET device 31, including a single gate region 42a. The elementary cell of FIG. 4 comprises structural and functional elements corresponding to those already described with reference to FIG. 2, which are designated by corresponding reference numbers and are not described any further.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a substrate having a first surface;
a body region in the substrate;
a source region in the body region;
a first trench and a second trench in the substrate, the first trench and the second trench extending through the body region and the source region, the first trench having a first end in the substrate, the second trench having a second end in the substrate;
a first gate dielectric on sidewalls and a bottom of the first trench;
a second gate dielectric on sidewalls and a bottom of the second trench;
a first gate electrode on the first gate dielectric in the first trench, a first surface of the first gate electrode being coplanar with the first surface of the substrate;
a second gate electrode on the second gate dielectric in second trench, a first surface of the second gate electrode being coplanar with the first surface of the substrate;
a first shielding region at the first end of the first trench, in the substrate, the first shielding region being spaced from the first gate electrode by only the first gate dielectric; and
a second shielding region at the second end of the second trench, in the substrate, the first shielding region being spaced from the second gate electrode by only the second gate dielectric.

2. The device of claim 1, wherein the substrate has a first conductivity type, the body region has a second conductivity type different from the first conductivity type, and the first and second shielding regions have the second conductivity type.

3. The device of claim 1, wherein the first surface of the substrate is coplanar with a first surface of the body region and a first surface of the source region.

4. The device of claim 1, wherein the first gate region is a single, continuous region of a conductive material.

5. The device of claim 1, comprising a first dielectric layer on the first surface of the substrate, the first dielectric layer being directly coupled to the first gate dielectric and the first gate electrode.

6. The device of claim 5, wherein the first dielectric layer has a first dimension along a first direction greater than a second dimension of the first trench along the first direction.

7. A device, comprising:
a substrate having a first surface opposite a second surface along a first direction;
a body region in the substrate extending from the first surface of the substrate into the substrate along the first direction, the body region having a first surface coplanar with the first surface of the substrate;
a source region in the substrate extending from the first surface of the substrate into the body region along the first direction, the source region having a first surface coplanar with the first surface of the substrate;
a first trench in the substrate, the first trench extending along the first direction through the body region and the source region, the first trench having a first end in the substrate and a first dimension along a second direction transverse to the first direction;
a first gate dielectric in the first trench, the first gate dielectric covering the first end and a first plurality of sidewalls of the first trench;
a first gate electrode on the first gate dielectric in the first trench, a first surface of the first gate electrode being coplanar with the first surface of the substrate and the first surface of the source region;
a first dielectric layer on the first surface of the substrate, the first dielectric layer having a second dimension along the second direction greater than the first dimension; and
a first shielding region at the first end of the first trench, in the substrate, the first shielding region being spaced from the first gate electrode along the first direction by the first gate dielectric, a central axis of the first shielding region being aligned with a central axis of the first gate electrode and a central axis of the first trench along the first direction.

8. The device of claim 7, further comprising:
a second trench in the substrate, the second trench extending along the first direction through the body region and the source region, the second trench having a second end in the substrate, the second trench having a third dimension along the second direction;
a second gate dielectric in the second trench, the second gate dielectric covering the second end and a second plurality of sidewalls of the second trench;
a second gate electrode on the second gate dielectric in the second trench, a first surface of the second gate electrode being coplanar with the first surface of the substrate;
a second dielectric layer on the first surface of the substrate, the second dielectric layer having a fourth dimension along the second direction greater than the first and third dimensions; and
a second shielding region at the second end of the second trench, in the substrate, the first shielding region being spaced from the second gate electrode along the first direction by the second gate dielectric.

9. The device of claim 8, wherein the source region includes a first portion with a first surface extending along the first direction and a second surface extending along the second direction, the first surface of the first portion being directly coupled to the first gate dielectric and the second surface of the first portion being directly coupled to the first dielectric layer.

10. The device of claim 9, wherein the source region includes a second portion with a first surface extending along the first direction and a second surface extending along the second direction, the first surface of the second portion being directly coupled to the second gate dielectric and the second surface of the second portion being directly coupled to the second dielectric layer.

11. The device of claim 10, wherein the second surface of the first portion and the second surface of the second portion are coplanar with the first surface of the substrate.

12. The device of claim 7, further comprising a source electrode on the first surface of the substrate, the source electrode being directly coupled to the body region, the source region, and the first dielectric layer.

13. The device of claim 12, further comprising a drain electrode on the second surface of the substrate.

14. The device of claim 8, wherein the first and third dimensions are substantially equal.

15. The device of claim 7, wherein the first shielding region has a third dimension along the second direction smaller than the first dimension.

16. The device of claim 15, wherein the third dimension of the first shielding region is greater than a fourth dimension along the second direction of the first gate electrode.

17. The device of claim 7, wherein the first plurality of sidewalls of the first trench extend along the first direction substantially perpendicular to the first surface of the substrate.

18. The device of claim 7, wherein the first gate dielectric has a first portion covering the first end with a first thickness along the first direction and a second portion covering a first sidewall of the first plurality of sidewalls with a second thickness along the second direction, the first thickness being substantially equal to the second thickness.

19. The device of claim 7, wherein the first gate dielectric layer has a first surface coplanar with the first surface of the substrate.

20. The device of claim 8, wherein the first gate electrode is separated from the first shielding region by only the first gate dielectric layer and the second gate electrode is separated from the second shielding region by only the second gate dielectric layer.

21. A device, comprising:
a substrate having a first surface opposite to a second surface;
a body region in the substrate;
a source region in the body region;
a first trench with substantially parallel sidewalls, the first trench being in the substrate and extending through the body region and through the source region;
a first shielding region in the substrate at an end of the first trench;
a first gate dielectric layer on the sidewalls and a bottom of the first trench, the first gate dielectric layer having a first surface coplanar with the first surface of the substrate;
a first gate electrode in the first trench, the first gate electrode extending from the end of the first trench to the first surface of the substrate.

22. The device of claim 21, wherein the source region includes a first surface coplanar with the first surface of the substrate and a second surface transverse to the first surface of the source region, the second surface being on the first gate dielectric.

23. The device of claim 21, further comprising a drain electrode on the second surface of the substrate and a source electrode on the first surface of the substrate, the source electrode being directly coupled to the source region and the body region.

24. A device, comprising:
a substrate having a first surface opposite a second surface along a first direction;
a body region in the substrate extending from the first surface of the substrate into the substrate along the first direction, the body region having a first surface coplanar with the first surface of the substrate;
a source region in the substrate extending from the first surface of the substrate into the body region along the first direction, the source region having a first surface coplanar with the first surface of the substrate;
a first trench and a second trench in the substrate, the first trench and the second trench extending along the first direction through the body region and the source region, the first trench having a first end in the substrate, the second trench having a second end in the substrate, the first trench having a first dimension along a second direction transverse to the first direction, the second trench having a second dimension along the second direction;
a first gate dielectric in the first trench, the first gate dielectric covering the first end and a first plurality of sidewalls of the first trench;
a second gate dielectric in the second trench, the second gate dielectric covering the second end and a second plurality of sidewalls of the second trench;
a first gate electrode on the first gate dielectric in the first trench, a first surface of the first gate electrode being coplanar with the first surface of the substrate;
a second gate electrode on the second gate dielectric in the second trench, a first surface of the second gate electrode being coplanar with the first surface of the substrate;
a first dielectric layer on the first surface of the substrate, the first dielectric layer having a third dimension along the second direction greater than the first dimension;
a second dielectric layer on the first surface of the substrate, the second dielectric layer having a fourth dimension along the second direction greater than the second dimension;
a first shielding region at the first end of the first trench, in the substrate, the first shielding region being spaced from the first gate electrode along the first direction by the first gate dielectric; and
a second shielding region at the second end of the second trench, in the substrate, the first shielding region being spaced from the second gate electrode along the first direction by the second gate dielectric.

25. The device of claim 24, wherein the substrate has a first conductivity type, the source region has the first conductivity type, the body region has a second conductivity type different from the first conductivity type, and the first and second shielding regions have the second conductivity type.
